(19) United States
(12) Patent Application Publication
(10) Pub. No.: US 2007/0048547 A1
(43) Pub. Date: Mar. 1, 2007

(54) Organic electro-luminescent device and material of hole-transport layer

(76) Inventors: Chan-Ching Chang, Longtan Township (TW); Chin-Hsin Chen, Taipei City (TW); Hsiao-Wen Huang, Yongkang City (TW); Ta-Ya Chu, Taipei City (TW); Chi-Hung Liao, Taichung City (TW); Shih-Kuei Lo, Taoyuan City (TW); Shuenn-Jiun Tang, Jhubei City (TW)

Correspondence Address: J.C. Patents, Inc., Suite 250, 4 Venture, Irvine, CA, 92618, US

(21) Appl. No.: 11/270,268

(22) Filed: Nov. 8, 2005

(30) Foreign Application Priority Data
Aug. 31, 2005 (TW) 94129915

(51) Int. Cl. H01L 51/54; H05B 33/12

(52) U.S. Cl. 428/690; 428/917; 313/504; 313/506; 257/E51.049

(57) ABSTRACT

An organic electro-luminescent device including an anode, a cathode, a light-emitting layer and a hole-transport layer is provided. The light-emitting layer is disposed between the anode and the cathode. The hole-transport layer is disposed between the light-emitting layer and the anode. The hole-transport layer has a formula as follows: 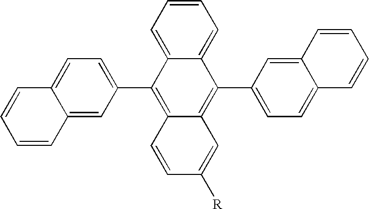 wherein R is an alkyl group having 1˜3 carbon atoms.

### CROSS-REFERENCE TO RELATED APPLICATION

This application claims the priority benefit of Taiwan application serial no. 94129915, filed on Aug. 31, 2005. All disclosure of the Taiwan application is incorporated herein by reference.

### BACKGROUND OF THE INVENTION

1. Field of the Invention

The present invention generally relates to a light-emitting device and a film material thereof. More particularly, the present invention relates to an organic electro-luminescent device and the material of a hole-transport layer.

2. Description of Related Art

Display devices having light weight and high efficiency such as LCD have been broadly developed. But LCD still has many problems, for example the viewing angle is not wide enough, the response time is not high enough to apply to high speed cartoons, and it needs a back light module to cooperate with and so on.

Among the newly developed display panels, organic electro-luminescent display (OELD) can overcome the above mentioned problems. Compared with other display panels, OLED has many advantages including self-illuminating screen, wide viewing angle, low power consumption, simple manufacturing process, low cost, a wide temperature operating range, a high response speed and full-color display. So, the OLED has become the major display product in the next generation.

The Organic electro-luminescent display (OELD) utilizes the self-illuminating property of the organic light-emitting material to display an image. The OELD comprises a pair of electrodes and an organic material layer sandwiched between the two electrodes. The organic material layer comprises organic light-emitting material. When a current travels through the electrodes, the hole and electron carriers moving inside the organic light-emitting material layer may collide and recombine with each other. A portion of the energy released by the recombination of electron-hole pairs may excite the organic light-emitting molecules into an excited state. When the excited molecule releases its energy and returns to a ground state, a definite portion of the energy is released as photons to emit light. Hence, the OLED panel will emit light on activation.

Generally, in the OLED having stacked films, NPB, N,N′-diphenyl-N,N′-(3-methylphenyl)-1,1-biphenyl-4,4′-diamine (TPD) and the like with the structure of triphenyamine are the most popular material of the hole-transport layer and are cooperated with the light-emitting layer composed of metal complex like tris-(8-hydroxy quinolinol)aluminium (Alq3). The above mentioned hole-transport layer having the characteristics of ionization potential lower than 5.7 eV and aromatic hydrocarbon group stacked above the light-emitting layer can make the hole and electron carriers recombine with each other inside the light-emitting layer, to emit light.

The brightness and light-emitting efficiency are important factors for the OLED. So, how to increase the brightness and light-emitting efficiency of the OLED is a critical issue.

### SUMMARY OF THE INVENTION

Accordingly, the present invention is directed to an organic electro-luminescent device, which utilizes a new hole-transport material as the hole-transport layer.

The present invention is also directed to providing an organic electro-luminescent device having higher light-emitting efficiency than that of the conventional one.

The present invention is to provide an organic electro-luminescent device for replacing the hole-transport material of the conventional one.

According to an embodiment of the present invention, the organic electro-luminescent device comprises an anode, a cathode, a light-emitting layer and a hole-transport layer. The light-emitting layer is disposed between the anode and the cathode. The hole-transport layer is disposed between the light-emitting layer and the anode. The hole-transport layer has a formula as follows: 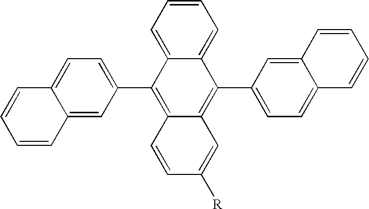
wherein R is an alkyl group having 1˜3 carbon atoms.

According to an embodiment of the present invention, the hole-transport layer is a P-type acceptor doped with 2-methyl-9,10-di(2-napthyl)anthracene (MADN) for example.

According to an embodiment of the present invention, the acceptor is FeCl3 or tetrafluoro-tetracyano-quinodimethane (F4-TCNQ).

According to an embodiment of the present invention, the organic electro-luminescent device further comprises a hole injection layer disposed between the anode and the hole-transport layer.

According to an embodiment of the present invention, the organic electro-luminescent device further comprises an electron-transport layer disposed between the cathode and the light-emitting layer.

According to an embodiment of the present invention, the organic electro-luminescent device further comprises an electron injection layer disposed between the cathode and the light-emitting layer.

According to an embodiment of the present invention, the above mentioned anode comprises transparent conductive material.

According to an embodiment of the present invention, the above mentioned cathode comprises metal material.

According to an embodiment of the present invention, the above mentioned light-emitting layer comprises small molecule organic electro-luminescent material.

According to an embodiment of the present invention, the above mentioned light-emitting layer comprises polymer electro-luminescent material.

According to another embodiment of the present invention, an organic electro-luminescent device is described. The organic electro-luminescent device comprises a substrate, a plurality of organic electro-luminescent units and at least one charge generation layer. The organic electro-luminescent units are stacked on the substrate. At least one charge generation layer is disposed between two of the adjacent organic electro-luminescent units. Besides, each organic electro-luminescent unit comprises an anode, a cathode, a light-emitting layer and a hole-transport layer. The light-emitting layer is disposed between the anode and the cathode. The hole-transport layer is disposed between the light-emitting layer and the anode, and it has a formula as follows: 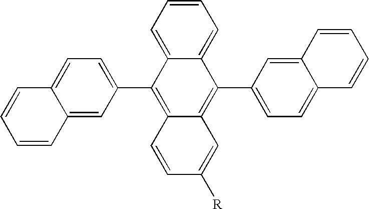
wherein R is an alkyl group having 1˜3 carbon atoms.

According to an embodiment of the present invention, the hole-transport layer is a P-type acceptor doped with 2-methyl-9,10-di(2-napthyl)anthracene (MADN) for example.

According to an embodiment of the present invention, the acceptor is FeCl3 or tetrafluoro-tetracyano-quinodimethane (F4-TCNQ).

According to an embodiment of the present invention, each organic electro-luminescent unit further comprises a hole injection layer disposed between the anode and the hole-transport layer.

According to an embodiment of the present invention, each organic electro-luminescent unit further comprises an electron-transport layer disposed between the cathode and the light-emitting layer.

According to an embodiment of the present invention, each organic electro-luminescent unit further comprises an electron injection layer disposed between the cathode and the light-emitting layer.

According to an embodiment of the present invention, the anode of each organic electro-luminescent unit comprises transparent conductive material.

According to an embodiment of the present invention, the cathode of each organic electro-luminescent unit comprises metal material.

According to an embodiment of the present invention, the light-emitting layer of each organic electro-luminescent unit comprises small molecule organic electro-luminescent material.

According to an embodiment of the present invention, the above mentioned light-emitting layer comprises polymer electro-luminescent material.

According to another embodiment of the present invention, a material of the hole-transport layer is disclosed. The material of the hole-transport layer has the following formula: 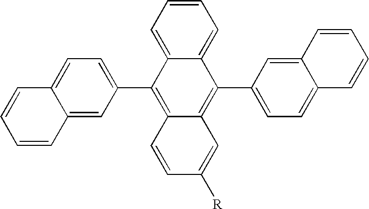
wherein R is an alkyl group having 1˜3 carbon atoms.

The invention utilizes a new organic material 2-methyl-9,10-di(2-napthyl)anthracene (MADN) for replacing the NPB, TPD and the like in the conventional structure as the hole-transport layer. The hole-transport layer made of new organic material not only can replace the hole-transport material of the conventional one but also can apply to the organic electro-luminescent device composed of stacked films. So, the organic electro-luminescent device having the new organic material will have higher light-emitting efficiency than that of the conventional one.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic cross-section view showing an organic electro-luminescent device according to the first embodiment of the present invention.

FIG. 1B is a schematic cross-section view showing an organic electro-luminescent device according to the second embodiment of the present invention.

FIG. 2A is a schematic cross-section view showing an organic electro-luminescent device according to the third embodiment of the present invention.

FIG. 2B is a schematic cross-section view showing an organic electro-luminescent device according to the fourth embodiment of the present invention.

FIG. 3 shows a relationship of the current and voltage of the OLED devices when using MADN and NPB as the hole-transport layer under forward and reverse bias conditions, respectively.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

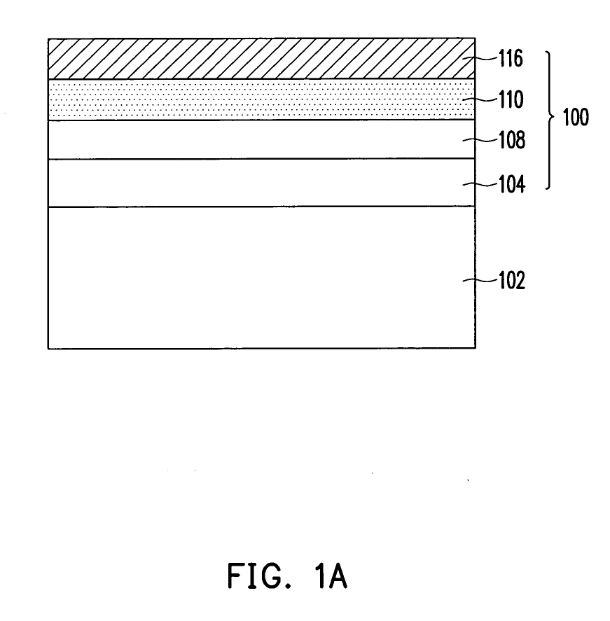

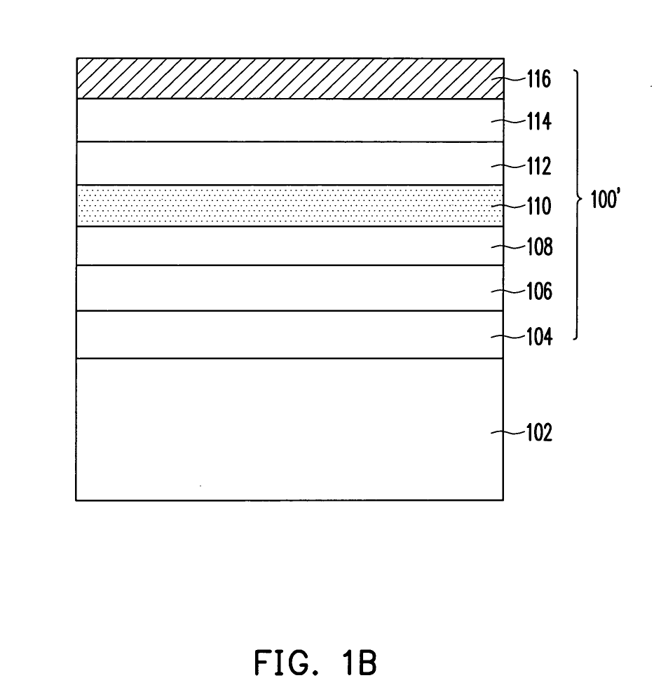

FIG. 1A is a schematic cross-section view showing an organic electro-luminescent device according to the first embodiment of the present invention. Please refer to FIG. 1A, the organic electro-luminescent device 100 comprises an anode 104, a hole-transport layer 108, a light-emitting layer 110 and a cathode 116. The anode 104 is arranged on a substrate 102. The light-emitting layer 110 is disposed between the anode 104 and the cathode 116. The hole-transport layer 108 is disposed between the light-emitting layer 110 and the anode 104. The hole-transport layer 108 has a formula as follows: 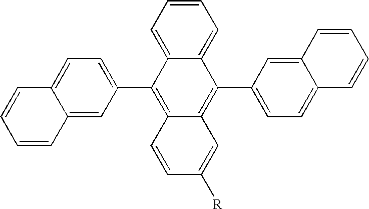
wherein R is an alkyl group having 1˜3 carbon atoms. The hole-transport layer is a P-type acceptor doped with 2-methyl-9,10-di(2-napthyl)anthracene (MADN) for example. Furthermore, the acceptor is FeCl3 or tetrafluoro-tetracyano-quinodimethane (F4-TCNQ).

Besides, in one embodiment of the present invention, the anode 104 comprises transparent conductive material, the cathode 116 comprises metal material, and the light-emitting layer 110 comprises small molecule organic electro-luminescent material or polymer electro-luminescent material.

In another embodiment of the present invention, the organic electro-luminescent device further comprises a hole injection layer, an electron-transport layer and an electron injection layer. FIG. 1B is a schematic cross-section view showing an organic electro-luminescent device according to the second embodiment of the present invention. As shown in FIG. 1B, the organic electro-luminescent device 100 comprises an anode 104, a hole injection layer 106, a hole-transport layer 108, a light-emitting layer 110, an electron-transport layer 112, an electron injection layer 114 and a cathode 116. The anode 104 is arranged on a substrate 102. The hole injection layer 106 is arranged on the anode 104. The hole-transport layer 108 is disposed on the hole injection layer 106. The light-emitting layer 110 is placed on the hole-transport layer 108. The electron-transport layer 112 is disposed on the light-emitting layer 110. The electron injection layer 114 is arranged on the electron-transport layer 112. The cathode 116 is placed on the electron injection layer 114.

The organic electro-luminescent device of the invention is not restricted to the four-layer structure shown in FIG. 1A or the seven-layer structure shown in FIG. 1B. It can be a five-layer or a six-layer structure according to the demand. For example, in one embodiment of the present invention, except to the anode, the hole-transport layer, the light-emitting layer and the cathode, the organic electro-luminescent device can further comprise an electron-transport layer disposed between the cathode and the light-emitting layer. In another embodiment of the present invention, except to the anode, the hole-transport layer, the light-emitting layer and the cathode, the organic electro-luminescent device can further comprise an electron injection layer disposed between the cathode and the light-emitting layer. The mentioned hole injection layer, the electron-transport layer and the electron injection layer can use the same material as that in the conventional structure and their material is not limited. The organic electro-luminescent can comprise one, any two or all of the hole injection layer, the electron-transport layer and the electron injection layer according to the demand.

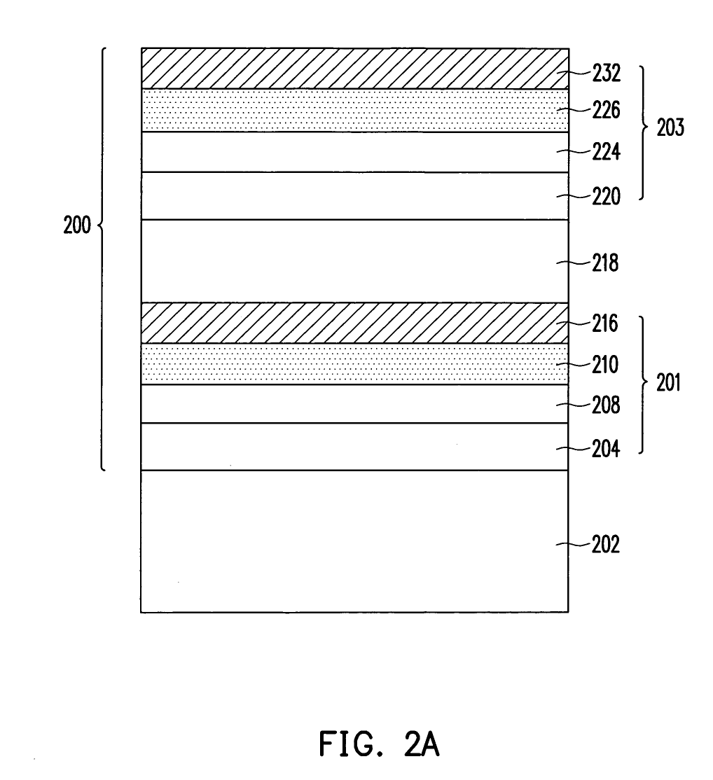

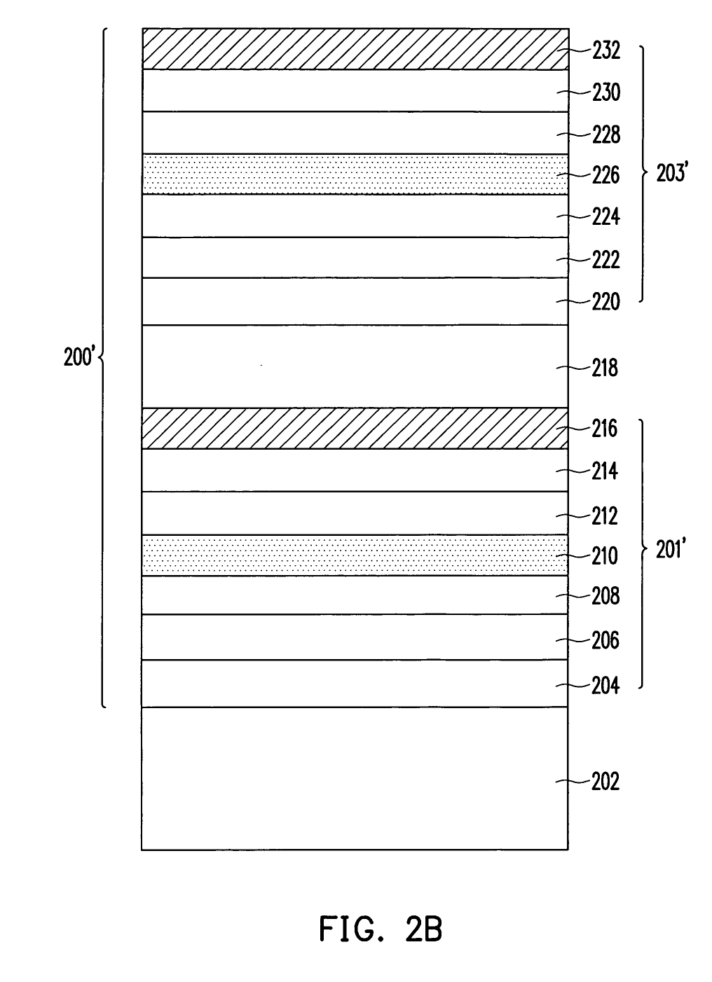

FIG. 2A is a schematic cross-section view showing an organic electro-luminescent device according to the third embodiment of the present invention. As shown in FIG. 2A, the organic electro-luminescent device 200 comprises a plurality of organic electro-luminescent units 201,203 stacked on a substrate 202 and at least one charge generation layer 218 sandwiched between two adjacent organic electro-luminescent units 201,203. More specifically, the organic electro-luminescent units 201 is arranged on the substrate 202, the charge generation layer 218 is arranged on the organic electro-luminescent units 201, and the organic electro-luminescent units 203 is arranged on the charge generation layer 218. In this embodiment, the organic electro-luminescent units 200, 201 are four-layer structures. The organic electro-luminescent unit 200 comprises an anode 204, a hole-transport layer 208, a light-emitting layer 210 and a cathode 216. The organic electro-luminescent unit 201 comprises an anode 220, a hole-transport layer 224, a light-emitting layer 226 and a cathode 232. The hole-transport layers 208, 224 have a formula as follows: 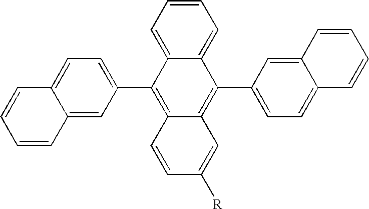
wherein R is an alkyl group having 1˜3 carbon atoms.

According to an embodiment of the present invention, the material of the charge generation layer 218 is WO3. The anode 220 comprises transparent conductive material. The cathodes 216, 232 comprise metal material. The light-emitting layers 210,226 comprise small molecule organic electro-luminescent material or polymer electro-luminescent material.

Each of the organic electro-luminescent device can also have a hole injection layer, an electron-transport layer and an electron injection layer. As shown in FIG. 2B, the organic electro-luminescent device 200′ includes organic electro-luminescent units 201′, 203′ and a charge generation layer 218. The organic electro-luminescent units 201′ comprises an anode 214, a hole injection layer 206, a hole-transport layer 218, a light-emitting layer 210, an electron-transport layer 212, an electron injection layer 214 and a cathode 216. The organic electro-luminescent units 203′ comprises an anode 220, a hole injection layer 222, a hole-transport layer 224, a light-emitting layer 226, an electron-transport layer 228, an electron injection layer 230 and a cathode 232.

The organic electro-luminescent units 201′, 203′ are not restricted to a four-layer or a seven-layer structure. It can be a five-layer or a six-layer structure according to the demand. The organic electro-luminescent units 201′, 203′ may have the same or different number of films, and they can be composed of the same or different film layers.

Further, the charge generation layer 218 sandwiched between two adjacent organic electro-luminescent units 201′, 203′ can be used as the cathode of the lower organic electro-luminescent unit and the anode of the upper organic electro-luminescent unit. So, the cathode 216 of the organic electro-luminescent unit 201′ and the anode 220 of the organic electro-luminescent unit 203′ can be omitted.

In this invention, the stacked type organic electro-luminescent unit 200′ utilizing MADN as the hole-transport layer and the charge generation layer for connecting two organic electro-luminescent units can provide higher light-emitting efficiency than that of the conventional one.

For further understanding the characteristics of MADN, which is the material of the hole-transport layer of the invention, a comparison between two light-emitting devices using MADN and NPB as the hole-transport layer is shown in the following.

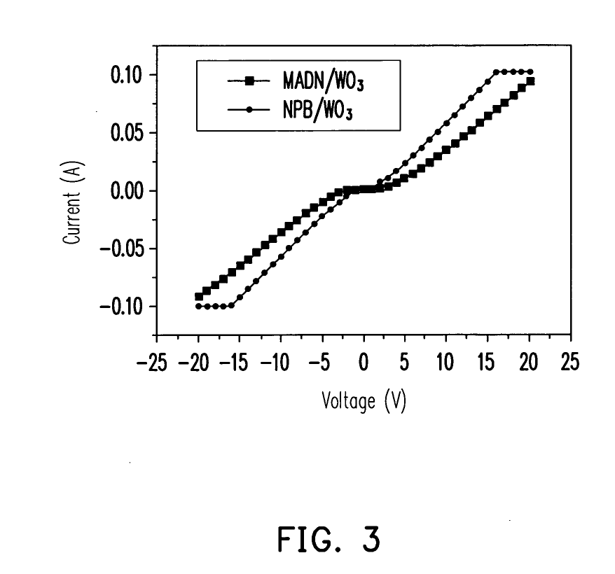

First, comparing the energy level of the lowest unoccupied molecular orbital (LUMO) and the highest occupied molecular orbital (HOMO) potential of MADN and NPB. The LUMO potential of MADN and NPB are all 2.3 eV. The HOMO potential of MADN is 5.5 eV, and the HOMO potential of NPB is 5.4 eV. Please refer to FIG. 3, which shows a relationship of the current and voltage of the OLED devices when using MADN and NPB as the hole-transport layer under forward and reverse bias conditions respectively.

It is clear that the LUMO and HOMO potential of MADN and NPB is similar. From FIG. 3, the organic electro-luminescent devices using MADN and NPB as the hole-transport layer have similar curves. So, it proves that MADN can also be used as the material of the hole-transport layer. The invention provides a new opportunity for the hole-transport layer.

In summary, the invention has the following advantages:

1. The invention provides a new material (MADN) of the hole-transport layer for replacing the organic material like NPB and TPD of the conventional structure.

2. The hole-transport layer composed of MADN can apply to the stacked type organic electro-luminescent devices. The organic electro-luminescent device having the new organic material will have higher light-emitting efficiency than that of the conventional one.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An organic electro-luminescent device, comprising:
an anode;
a cathode;
a light-emitting layer disposed between the anode and the cathode; and
a hole-transport layer disposed between the light-emitting layer and the anode, wherein the hole-transport layer has a formula as follows: 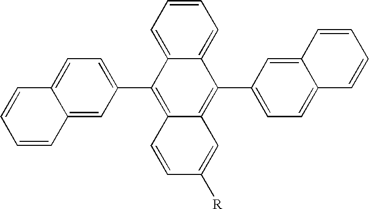
wherein R is an alkyl group having 1˜3 carbon atoms.

2. The organic electro-luminescent device according to claim 1, wherein the hole-transport layer is a P-type acceptor doped with 2-methyl-9,10-di(2-napthyl)anthracene (MADN) for example.

3. The organic electro-luminescent device according to claim 2, wherein the acceptor comprises FeCl3 or tetrafluoro-tetracyano-quinodimethane (F4-TCNQ).

4. The organic electro-luminescent device according to claim 1, further comprises a hole injection layer disposed between the anode and the hole-transport layer.

5. The organic electro-luminescent device according to claim 1, further comprises an electron-transport layer disposed between the cathode and the light-emitting layer.

6. The organic electro-luminescent device according to claim 1, further comprises an electron injection layer disposed between the cathode and the light-emitting layer.

7. The organic electro-luminescent device according to claim 1, wherein a material of the anode comprises transparent conductive material.

8. The organic electro-luminescent device according to claim 1, wherein a material of the cathode comprises metal material.

9. The organic electro-luminescent device according to claim 1, wherein the light-emitting layer comprises small molecule organic electro-luminescent material.

10. The organic electro-luminescent device according to claim 1, wherein the light-emitting layer comprises polymer electro-luminescent material.

11. An organic electro-luminescent device, comprising:
a plurality of organic electro-luminescent units stacked on a substrate, wherein each of the organic electro-luminescent units comprising:
an anode;
a cathode;
a light-emitting layer disposed between the anode and the cathode; and
a hole-transport layer disposed between the light-emitting layer and the anode, wherein the hole-transport layer has a formula as follows: 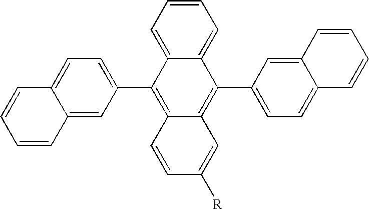
wherein R is an alkyl group having 1˜3 carbon atoms; and
at least one charge generation layer disposed between two of the adjacent organic electro-luminescent units.

12. The organic electro-luminescent device according to claim 11, wherein the hole-transport layer is a P-type acceptor doped with 2-methyl-9,10-di(2-napthyl)anthracene (MADN) for example.

13. The organic electro-luminescent device according to claim 12, wherein the acceptor comprises FeCl3 or tetrafluoro-tetracyano-quinodimethane (F4-TCNQ).

14. The organic electro-luminescent device according to claim 11, wherein a material of the charge generation layer comprises WO₃.

15. The organic electro-luminescent device according to claim 11, wherein each organic electro-luminescent unit further comprises a hole injection layer disposed between the anode and the hole-transport layer.

16. The organic electro-luminescent device according to claim 11, wherein each organic electro-luminescent unit further comprises an electron-transport layer disposed between the cathode and the light-emitting layer.

17. The organic electro-luminescent device according to claim 11, wherein each organic electro-luminescent unit further comprises an electron injection layer disposed between the cathode and the light-emitting layer.

18. The organic electro-luminescent device according to claim 11, wherein a material of the anode of each organic electro-luminescent unit comprises transparent conductive material.

19. The organic electro-luminescent device according to claim 11, wherein a material of the cathode of each organic electro-luminescent unit comprises metal material.

20. The organic electro-luminescent device according to claim 11, wherein a material of the light-emitting layer of each organic electro-luminescent unit comprises small molecule organic electro-luminescent material.

21. The organic electro-luminescent device according to claim 11, wherein a material of the light-emitting layer of each organic electro-luminescent unit comprises polymer electro-luminescent material.

22. A material of hole-transport layer, comprising a formula as follows: 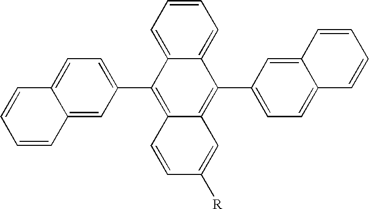
wherein R is an alkyl group having 1˜3 carbon atoms.
